(19) United States
(12) Patent Application Publication
(10) Pub. No.: US 2006/0258078 A1
(43) Pub. Date: Nov. 16, 2006

(54) Atomic layer deposition of high-k metal oxides

(76) Inventors: Sang-In Lee, Cupertino, CA (US); Yoshihide Senzaki, Austin, TX (US); Sang-Kyoo Lee, Seoul (KR)

Correspondence Address: DORSEY & WHITNEY LLP, 555 CALIFORNIA STREET, SUITE 1000, SUITE 1000, SAN FRANCISCO, CA, 94104, US

(21) Appl. No.: 10/524,814

(22) PCT Filed: Aug. 18, 2003
(86) PCT No.: PCT/US03/25738

§ 371 Date: May 5, 2006

Related U.S. Application Data
(60) Provisional application No. 60/404,372, filed on Aug. 18, 2002.

(51) Int. Cl. H01L 21/8238

(52) U.S. Cl. 438/216; 438/261; 438/595; 257/E21.192

(57) ABSTRACT

The present invention relates to the atomic layer deposition (“ALD”) of high k dielectric layers of metal oxides containing Group 4 metals, including hafnium oxide, zirconium oxide, and titanium oxide. More particularly, the present invention relates to the ALD formation of Group 4 metal oxide films using an metal alkyl amide as a metal organic precursor and ozone as a co-reactant.

### CROSS-REFERENCE TO RELATED APPLICATIONS

This application is related to, and claims priority to, U.S. Provisional Patent Application No. 60/404,372, entitled Atomic Layer Deposition of High-k Metal Oxides for Gate and Capacitor Dielectrics, filed Aug. 18, 2002, the entire disclosure of which is hereby incorporated by reference.

### FIELD OF THE INVENTION

The present invention relates to the atomic layer deposition (“ALD”) of high k dielectric films of metal oxide that contain Group 4 metals (Group 4 being the new periodic table notation which corresponds to Group IVA in the previous IUPAC form and Group IVB in the CAS version), including hafnium oxide (HfO₂), zirconium oxide (Z₁O₂) and titanium oxide (TiO₂), for gate and/or capacitor applications. More particularly, the present invention relates to the ALD formation of Group 4 metal oxide films using a metal alkyl amide and ozone.

### BACKGROUND OF THE INVENTION

The speed and functionality of computers doubles every year, facilitated in large part by the shrinking dimensions of integrated circuits. Currently, the smallest dimension in modern circuits is the thickness of the gate insulator, which separates the controlling electrode (“gate electrode”) from the controlled current in the silicon. Traditionally, the gate insulator has been made from silicon dioxide (SiO₂) and/or silicon nitride (SiN). Such insulators are now as thin as 20 Å. However, conventional gate dielectrics suffer from leakage and reliability deficiencies as the thickness decreases below 20 Å.

Accordingly, efforts are underway to find alternative insulators. To date, efforts have focused largely on high dielectric constant (high “k”) materials. As used herein, a material is “high k” if its dielectric constant “k” is higher than the dielectric constant of silicon oxide (k=3.9).

High k dielectrics that have been investigated include Group 4 metal oxides such as hafnium dioxide (HfO₂) (k˜20-25) and zirconium dioxide (ZrO₂) (k˜20-25). In general, these materials exhibit high permittivity, good thermal stability, and large band offset to silicon. However, charge trapping related to Vt (threshold voltage) instability, and electron mobility degradation in MOSFET performance are concerns. As the integrated circuit device scale approaches a 65 nm node, the need for improved high-k gate dielectrics to replace silicon dioxide is rapidly increasing. In fact, the need for high-k dielectrics with CMOS integration was identified in the International Technology Roadmap for Semiconductors.

In addition, prior art deposition techniques, such as chemical vapor deposition (CVD), are increasingly unable to meet the requirements of advanced thin films. While CVD processes can be tailored to provide conformal films with improved step coverage, CVD processes often require high processing temperatures, result in the incorporation of high impurity concentrations, and have poor precursor or reactant utilization efficiency. For instance, one of the obstacles of making high k gate dielectrics is the formation of interfacial silicon oxide layers during CVD processes. Another obstacle is the limitation of prior art CVD processes in depositing ultra thin films for high k gate dielectrics on a silicon substrate.

Accordingly, efforts are underway to develop improved methods for depositing materials in pure form with uniform stoichiometry, thickness, conformal coverage, abrupt interface, smooth surface, and reduced grain boundaries, cracks and pinholes. ALD is the latest method to be developed. In ALD, precursors and co-reactants are brought to the surface of a growing film separately, through alternating pulses and purges, to generate a single mono-layer of film growth per pulse cycle. Layer thickness is controlled by the total number of pulse cycles. ALD has several advantages to CVD. ALD can be performed at comparatively lower temperatures which is compatible with the industry's trend toward lower temperatures, and can produce conformal thin film layers. More advantageously, ALD can control film thickness on an atomic scale, and can be used to “nano-engineer” complex thin films. Accordingly, further developments in ALD are highly desirable.

The ALD formation of zirconium oxide using zirconium tetra-t-butoxide has been reported. See U.S. Pat. No. 6,465,371 (“Lim”). In addition, the ALD formation of hafnium oxide using hafnium tetra-dimethyl-amide (“TDMAHf”) and hafnium tetra-ethylmethyl-amide (“Hf-TEMA”) has been reported. See Vapor Deposition Of Metal Oxides And Silicates: Possible Gate Insulators For Future Microelectronics, R. Gordon et al., Chem. Mater., 2001, pp. 2463-2464 and Atomic Layer Deposition of Hafnium Dioxide Films From Hafnium Tetrakis(ethylmethylamide) And Water, K. Kukli et al., Chem. Vap. Deposition, 2002, Vol. 8, No. 5, pp. 199-204, respectively. However, none of these references teach the preferred use of a metal alkyl amide as a metal organic precursor in combination with ozone as an oxidant.

### SUMMARY OF THE INVENTION

The invention provides ALD processes for forming high k Group 4 metal oxide films, including hafnium oxide (HfO₂), zirconium oxide (ZrO₂), and titanium oxide (TiO₂), to replace silicon dioxide in gate and/or capacitor dielectric applications. The most preferred metal oxide is hafnium oxide. Hafnium oxide exhibits superior thermal stability and, thereby, results in less interfacial silicon dioxide growth.

The method entails an atomic layer deposition process wherein separate pulses of metal alkyl amide and ozone are introduced into a reaction chamber containing a substrate to grow a film of metal oxide on the substrate. The method is repeated until a film of target thickness is achieved.

More specifically, the method entails the following pulse cycle: first, a metal alkyl amide is pulsed into the reaction chamber; second, the reaction chamber is purged of unreacted metal alkyl amide and by products; third, ozone gas is pulsed into the reaction chamber; and fourth and finally, un-reacted ozone and by products are purged from the reaction chamber. Alternatively, ozone is pulsed and purged first, followed by pulse and purge of a metal alky lamide precursor. The pulse cycle is repeated as many times as necessary to achieve the target film thickness.

By using ozone in the ALD process, as opposed to conventional oxidants such as steam, the fixed and trapped charges in the resultant metal oxide film are significantly reduced. In addition, by using ozone in the ALD process, as opposed to conventional oxidants such as oxygen gas, the required operating temperatures for the ALD process are significantly reduced.

The use of a metal alkyl amide as the metal organic precursor in the ALD process significantly reduces carbon contamination in the resultant film compared to other precursors, such as metal alkyls and metal alkoxides. This is especially true for metal alkyl amides wherein the alkyl amide ligands are ethylmethyl amide ligands.

The high k metal oxide films produced in accordance with the invention are useful as dielectrics in gates and capacitors. When used as a gate dielectric, the high k dielectric films are formed on a substrate, generally a silicon wafer, between one or more n or p doped channels. Then an electrode, such as a N-or P-doped polycrystalline silicon electrode, is formed over the dielectric to complete the gate. When used as a capacitor dielectric, the high k dielectric films are formed between two conductive plates.

### BRIEF DESCRIPTION OF THE DRAWINGS

The invention will be described in detail with reference to the following figures, wherein:

FIG. 1 is a flow diagram that outlines the ALD pulse cycle of the instant invention; and

FIG. 2 illustrates the use of a high k dielectric film produced in accordance with the invention in a gate.

### DETAILED DESCRIPTION OF THE PREFERRED EMBODIMENTS

The invention provides ALD processes for forming high k Group 4 metal oxide films to replace silicon dioxide in gate and/or capacitor dielectric applications. Such metal oxides include hafnium oxide (HfO₂), zirconium oxide (ZrO₂), and titanium oxide (TiO₂). The most preferred metal oxide is hafnium oxide.

Prior to starting the pulse cycle, a substrate, generally a silicon wafer, is placed into a reaction chamber, often through a valve located at one end of the chamber. Preferably, the silicon wafer has been cleaned with hydrogen fluoride to remove native silicon dioxide.

The substrate sits on a heatable wafer holder that supports and heats the substrate to the desired reaction temperature. Once the substrate is properly positioned, the pulse cycle can begin.

Generally, prior to the first pulse in the pulse cycle, the wafer is heated to a temperature ranging from about 100° C. to about 500° C., and preferably ranging from about 200° C. to about 400° C. This temperature is maintained throughout the process.

Generally, prior to the first pulse in the pulse cycle, the reaction chamber is also brought to a pressure of about 0.1 to 5 Torr, and preferably about 0.1 to 2 Torr. This pressure is also maintained throughout the process.

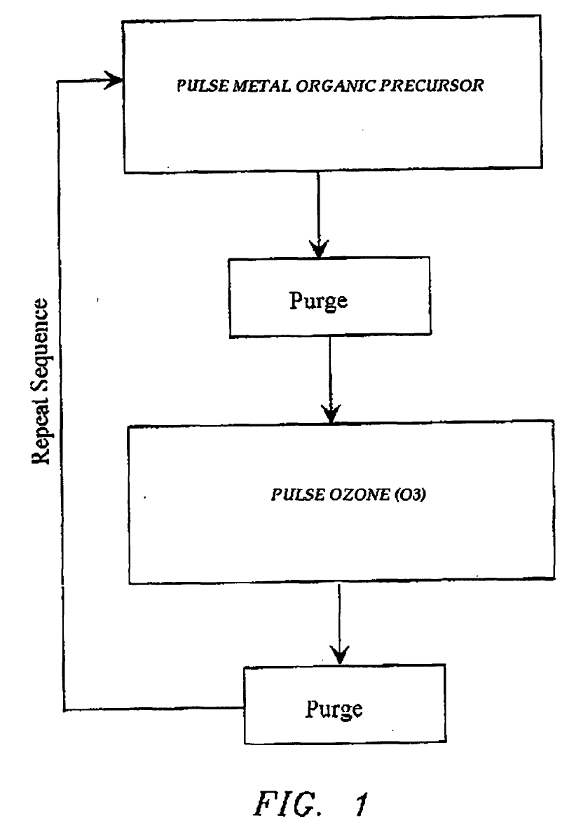

The pulse cycle is visually illustrated in FIG. 1. The pulse cycle comprises the following steps:

First, a volatile liquid metal alkyl amide is volatilized and pulsed into the reaction chamber as a gas. The metal alkyl amide is chemi-absorbed onto the surface of the substrate. In general, the metal alkyl amide is introduced over a period preferably ranging from about 0.1 to about 5 seconds at a flow rate ranging from about 0.1 to about 1100 standard cubic centimeters per minute (“sccm”). The metal alkyl amide may be introduced in combination with an inert carrier gas, such as argon, nitrogen or helium gas. Alternatively, the metal alkyl amide can be introduced in pure form.

Suitable metal alkyl amides include compounds conforming to the following formula:
M(NR¹R²)ₙ
wherein “M” is a Group 4 metal including hafnium, zirconium and titanium, wherein “R¹” and “R²,” independently, are selected from the group comprising substituted or unsubstituted linear, branched, and cyclic alkyls, and “n” is 4. Preferably, “R¹” and “R²” are, individually, a C₁-C₆ alkyl, such as methyl and ethyl, since these ligands reduce carbon contamination in the resultant film. Even more preferably, the ligands “NR³R⁴” are ethylmethyl amides. The use of metal alkyl amides with ethylmethyl amide ligands generates the least carbon contamination in the metal oxide film. For example, Hf-TEMA generates less carbon contamination than closely related compounds, such as hafnium tetramethyl amide and hafnium tetraethyl amide, as well as generating less carbon contamination than unrelated compounds, such as hafnium tetra-t-butoxide.

Second, the reaction chamber is purged of unreacted metal organic precursor and by product using, for example, an inactive purge gas or a vacuum purge. Inactive purge gases include argon, nitrogen and helium gas. The purge gas is pulsed into the reaction chamber over a period generally ranging from about 0.1 to about 5 seconds at a flow rate generally ranging from about 0.1 to about 1100 sccm.

Third, ozone gas is pulsed into the reaction chamber over a period generally ranging from about 0.1 to about 5 seconds at a flow rate generally ranging from about 0.1 to about 1100 sccm. The ozone can be introduced with an inert gas, such as argon, nitrogen or helium gas. Alternatively, the ozone can be added in pure form. However, by “pure” it is not meant that no oxygen gas is present. Oxygen gas is a precursor to ozone and usually remains as a contaminant in ozone to some degree. It is believed that the ozone severs the ligands in the metal organic precursor mono-layer and provides reactive oxygen that bind the metal groups to form metal oxide.

By using ozone in the ALD process, as opposed to conventional oxidants such as oxygen gas and steam, the fixed and trapped charges in the resultant metal oxide film are reduced. In addition, the required operating temperatures are reduced. Traditionally, oxygen gas and steam have been preferred oxidants for ALD processes, whereas ozone has been recognized as an oxidant but disfavored due to its relatively high instability. However, it has been discovered that ozone is actually the preferred oxidant in the formation of metal oxide films by ALD. Whereas oxygen gas requires operating temperatures around 400° C. or above, ozone permits operating temperatures below 300° C. Whereas steam causes hydroxyl contamination in the resultant film, ozone produces films free of such contamination.

Fourth, and finally, the reaction chamber is purged of unreacted ozone and by-product. This second purging step is generally conducted in the same manner as the first purging step.

This completes one cycle of the ALD process. The end result is the formation of one mono-layer of Group 4 metal oxide film on the substrate. The pulse cycle is then repeated as many times as necessary to obtain the desired film thickness. The layer by layer ALD growth provides excellent coverage over large substrate areas and provides excellent step coverage.

Preferred Group 4 metal oxide films formed in accordance with the invention include hafnium oxide (HfO₂), zirconium oxide (ZrO₂), and titanium oxide (TiO₂) films. The most preferred metal oxide film is hafnium oxide. Hafnium oxide exhibits superior thermal stability and, thereby, results in less interfacial silicon dioxide growth.

A hafnium oxide mono-layer is preferably formed on a silicon substrate by pulsing Hf-TEMA, followed by a purge, followed by a pulse of ozone, followed by a second purge. In this case, higher deposition rates result from higher pressure, higher precursor pulse time (lower flow rate), higher wafer temperature and lower ozone purge time. Better uniformity results from lower process pressure and lower wafer temperature. Fewer undesirable particles are formed using shorter purge times.

The hafnium oxide deposition using a Hf-TEMA precursor is preferably done at a wafer temperature range of 250-300° C., a process pressure of 0.5 Torr and a source canister temperature of 70° C. Preferably, the chamber containing the wafers is pre-pressurized and pre-heated over a 120 second period. Then the following pulse cycle is performed: first, precursor in argon is pulsed into the chamber at a flow rate of 230 sccm for 2.5 seconds; second, argon is pulsed into the chamber at a pulse rate of 1040 sccm for 1 second; third, a 180 g/m³ concentration of ozone is pulsed into the chamber at a flow rate of 350 sccm for 2 seconds; fourth and finally, argon is pulsed into the chamber at a pulse rate of 1050 Sccm for 3 seconds. The pulse cycle is repeated 58 times, resulting in a film thickness of approximately 66 Å. The leakage current density at minus 1 volt (amps/cm²) is approximately 1.08E-07 (amps/cm²).

The ALD process of the instant invention can be used to create high k dielectrics for use in gate and capacitor structures. For example, the process can be used to create gates by forming a high k metal oxide film on a substrate, such as a doped silicon wafer, and capping the structure with a conductive layer, such as doped Poly Si. Alternatively, the process can be used to create capacitors by forming a high k metal oxide film between two conductive plates.

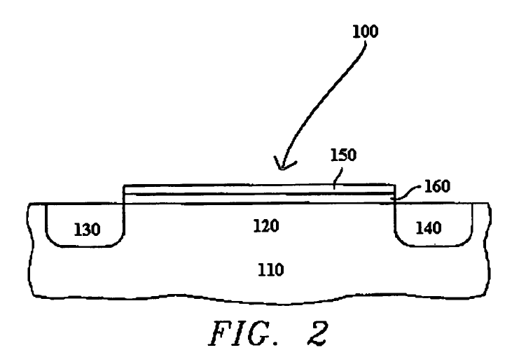

FIG. 2 is illustrative of the use of such high k dielectrics in a gate. In FIG. 2, a field effect transistor 100 is shown in cross section. The transistor includes a lightly p-doped silicon substrate 110 in which a n-doped silicon source 130 and a n-doped silicon drain 140 have been formed leaving a channel region 120 there between. A gate dielectric 160 is positioned over channel region 120. A gate electrode 150 is positioned over the gate dielectric 160, so that it is only separated from channel region 120 by the intermediate gate dielectric 160. When a voltage difference exists between source 130 and drain 140, no current flows through channel region 120, since one junction at the source 130 or drain 140 is back biased. However, by applying a positive voltage to gate electrode 150, current flows through channel region 120. The gate dielectric 160 is a high k metal oxide made in accordance with the ALD process of the invention.

It will be apparent to the skilled artisan that many variations of the instant invention are possible. For example, ozone can be generated and delivered in a number of ways. In addition, the particulars of ALD chambers, gas distribution devices, valves, timing, and the like, often vary. Other variations within the spirit and scope of this invention may exist that have not necessarily been detailed herein. Accordingly, the invention is only limited by the scope of the claims that follow.

What is claimed is:

1. A method of growing a metal oxide film on a substrate by atomic layer deposition comprising:
(i) introducing separate pulses of metal alkyl amide and ozone into a reaction chamber containing a substrate, wherein said metal is a Group 4 metal Hf, Zr, Ti; and
(ii) repeating step (i) until a film of a target thickness is achieved.

2. The method of claim 1, wherein the metal oxide is hafnium oxide.

3. The method of claim 1, wherein the metal alkyl amide has the formula M(NR¹R²)₄, wherein M represents a Group 4 metal, R¹ is an ethyl unit, and R² is a methyl unit.

4. The method of claim 1 wherein the substrate is silicon.

5. A method of forming a gate insulator for a transistor comprising:
(i) growing a metal oxide mono layer on a substrate by atomic layer deposition by introducing separate pulses of a metal alkyl amide and ozone into a reaction chamber containing a substrate, wherein said metal is a Group 4 metal;
(ii) repeating step (i) until a dielectric film of a target thickness is achieved; and
(iii) positioning a conductive layer over the dielectric layer.

6. The method of claim 5, wherein the metal oxides are hafnium oxide, zirconium oxide and titanium oxide.

7. The method of claim 5, wherein the metal alkyl amide has the formula M(NR¹R²)₄, wherein M represents a Group 4 metal, R¹ is an ethyl unit, and R² is a methyl unit.

8. The method of claim 5 wherein the substrate is silicon.

9. A method of forming a capacitor comprising:
(i) forming a metal oxide mono layer by atomic layer deposition by introducing separate pulses of a metal alkyl amide precursor and ozone into a reaction chamber containing a substrate, wherein said metal is a Group 4 metal;
(ii) repeating step (i) until a film of a target thickness is achieved; and
(iii) positioning said film between two electrodes.

10. The method of claim 9, wherein the metal oxides are hafnium oxide, ZrO₂, and TiO₂.

11. The method of claim 9, wherein the metal alkyl amide has the formula M(NR¹R²)₄, wherein M represents a Group 4 metal, R¹ is an ethyl unit, and R² is a methyl unit.

12. The method of claim 9, wherein the substrate is one of the two electrodes.
